(19) United States
(12) Patent Application Publication
(10) Pub. No.: US 2026/0322383 A1
(43) Pub. Date: Oct. 15, 2026

(54) POSITIVE VOLTAGE LEVEL SHIFTER WITH OUTPUT- CONTROLLED INTERMEDIATE NODE PULL-UP TRANSISTORS

(71) Applicant: GlobalFoundries U.S. Inc., Malta, NY (US)

(72) Inventors: Suresh Pasupula, Anantapur District (IN); Siva Kumar Chinthu, Bangalore (IN); Saumya Kumari Diwedi, Gorakhpur (IN)

(21) Appl. No.: 19/176,419

(22) Filed: Apr. 11, 2025

(51) Int. Cl. H03K 19/0185

(52) U.S. Cl. CPC H03K 19/018521

(57) ABSTRACT

Disclosed is structure for a positive voltage level shifter including: a first supply voltage node at a first positive voltage level (V1), a second supply voltage node at a second positive voltage level (V2) greater V1, and a ground node at 0.0 volts (V). The structure includes two symmetric branches, each branch includes: a stack of two pull-up transistors and two pull-down transistors series-connected between the second supply voltage node and ground node; an output node between the two pull-up transistors and the two pull-down transistors; and an input node connected to a control terminal of a bottom pull-down transistor in the stack. Each branch also includes an additional pull-up transistor, which is connected between the first positive supply voltage node and an intermediate node between the two pull-up transistors in the stack and which has a control terminal connected to the output node.

### BACKGROUND

The present disclosure relates to on-chip voltage level shifters and, more particularly, to embodiments of positive voltage level shifter.

Considerations in modern integrated circuit (IC) design include, but are not limited to, performance improvement, size scaling, and power consumption. Oftentimes design changes to improve one aspect of the design can yield an undesirable trade-off with respect to one or more of the other aspects of the design. For example, a positive voltage level shifter may be configured to translate (i.e., shift) an input signal (IN) that swings between 0.0 volts (V) and a first positive voltage level (V1), to an output signal (OUT) that swings between 0.0V and a higher second positive voltage level (V2) (e.g., where V2~2*V1). To reduce power consumption, positive voltage level shifters have been developed that include low-voltage transistors (e.g., transistors rated for 1.8V-operation, for 1.5V-operation, or for 0.8V-operation). However, within such positive voltage level shifters, some of the low-voltage transistors operate outside their safe operating area (SOA) specifications.

### SUMMARY

Disclosed herein are embodiments of a positive voltage level shifter (hereinafter referred to as the structure). Generally, the structure can include: a first supply voltage node, which is connected to receive a first positive supply voltage at a first positive voltage level, and a second supply voltage node, which is connected to receive a second positive supply voltage at a second positive voltage level that is greater than the first positive voltage level. The structure can further include two symmetric branches. Each branch can include multiple pull-up transistors. The pull-up transistors can include: a first pull-up transistor, which is connected between the second supply voltage node and an intermediate node; a second pull-up transistor, which is connected between the intermediate node and an output node; and a third pull-up transistor, which is connected between the first supply voltage node and the intermediate node and which has a control terminal connected to the output node.

In some embodiments of the structure, the pull-up transistors can be P-type field effect transistors (PFETs). That is, the structure can include: a first supply voltage node, which is connected to receive a first positive supply voltage at a first positive voltage level, and a second supply voltage node, which is connected to receive a second positive supply voltage at a second positive voltage level that is greater than the first positive voltage level. The structure can further include two symmetric branches. Each branch can include multiple pull-up transistors and, particularly, multiple PFETs. These PFETs can include: a first PFET, which is connected between the second supply voltage node and an intermediate node; a second PFET, which is connected between the intermediate node and an output node; and a third PFET, which is connected between the first supply voltage node and the intermediate node and which has a gate connected to the output node.

In some embodiments of the structure, each of the symmetric branches can include multiple pull-up transistors (e.g., multiple PFETs) and multiple-pull-down transistors (e.g., multiple N-type field effect transistors (NFETs)). That is, the structure can include: a first supply voltage node, which is connected to receive a first positive supply voltage at a first positive voltage level; a second supply voltage node, which is connected to receive a second positive supply voltage at a second positive voltage level that is greater than the first positive voltage level; and a ground node at 0.0 volts (V). The structure can further include two symmetric branches including a first branch and a second branch. The first and second branches can each include multiple pull-up transistors (e.g., PFETs) and multiple pull-down transistors (e.g., NFETs). Specifically, each branch can include a first pull-up transistor, a second pull-up transistor, a first pull-down transistor, and a second pull-down transistor connected in series between the second supply voltage node and ground. Each branch can further include a third pull-up transistor, which is connected between the first supply voltage node and an intermediate node located between the first pull-up transistor and the second pull-up transistor. The third pull-up transistor can have a control terminal, which is connected to an output node located between the second pull-up transistor and the first pull-down transistor. Each branch can further include a fourth pull-up transistor, which is connected between the first supply voltage node and an additional intermediate node located between the first pull-down transistor and the second pull-down transistor. The second pull-down transistor and the fourth pull-up transistor can have control terminals connected to an input node. Additionally, within this structure, the first pull-up transistor in the first branch and the first pull-up transistor in the second branch are cross coupled. Furthermore, the second pull-up transistor in the first branch, the second pull-up transistor in the second branch, the first pull-down transistor in the first branch, and the first pull-down transistor in the second branch have control terminals connected to the first supply voltage node.

It should be noted that all aspects, examples, and features of disclosed embodiments mentioned in the summary above can be combined in any technically viable way. That is, two or more aspects of any of the disclosed embodiments, including those described in this summary section, may be combined to form implementations not specifically described herein. The details of one or more implementations are set forth in the accompanying drawings and the description below. Other features, objects and advantages will be apparent from the description and drawings, and from the claims.

### BRIEF DESCRIPTION OF THE DRAWINGS

The present disclosure will be better understood from the following detailed description with reference to the drawings, which are not necessarily drawn to scale and in which:

FIG. 1 is a schematic diagram illustrating an embodiment of a positive voltage level shifter;

FIG. 2 is a timing diagram illustrating input voltage pulses to and output voltage pulses from the structure of FIG. 1; and

FIGS. 3A-3D are timing diagrams illustrating some of the voltage pulses of FIG. 2 during power-up and power-down of the positive voltage level shifter of FIG. 1.

### DETAILED DESCRIPTION

As mentioned above, considerations in modern integrated circuit (IC) design include, but are not limited to, performance improvement, size scaling, and power consumption. Oftentimes design changes to improve one aspect of the design can yield an undesirable trade-off with respect to one or more of the other aspects of the design. For example, a positive voltage level shifter may be configured to translate (i.e., shift) an input signal (IN) that swings between 0.0 volts (V) and a first positive voltage level (V1) to an output signal (OUT) that swings between 0.0V and a higher second positive voltage level (V2) (e.g., where V2~2*V1). To reduce power consumption, positive voltage level shifters have been developed that include low-voltage transistors (e.g., transistors rated for 1.8V-operation, for 1.5V-operation, or for 0.8V-operation). However, within such positive voltage level shifters, some of the low-voltage transistors operate outside their safe operating area (SOA) specifications.

For example, for metal oxide semiconductor field effect transistors (MOSFETs), SOA specifications can include maximum operating voltage limits, such as the maximum drain-source voltage (VDS), the maximum gate-source voltage (VGS), and the maximum operating gate-drain voltage (VGD). When only low-voltage MOSFETs are used in a conventional positive voltage level shifter to shift a low-voltage IN to a high-voltage OUT, violations of one or more of these maximum operating voltage limitations occur in one or more of the MOSFETs. Design modifications intended to avoid such violations have included, for example, the use of at least some high-asymmetric MOSFETs (e.g., laterally diffused metal oxide semiconductor field effect transistors (LDMOSFETs)) in place of at-risk low-voltage MOSFETs and/or the use of external biasing. Unfortunately, these design modifications add to circuit complexity, power consumption, and area.

In view of the foregoing, disclosed herein are embodiments of a positive voltage level shifter (hereinafter referred to as the structure), which includes only stress-free, low-voltage transistors. The structure can include: a first positive supply voltage node, which is connected to receive a first positive supply voltage at a first positive voltage level (V1) (e.g., 1.8 volts (V)), and a second positive supply voltage node, which is connected to receive a second positive supply voltage at a second positive voltage level (V2) that is greater than the first positive voltage level (e.g., V2~2*V1, such as 3.6V). The structure can further include two symmetric branches, each with multiple low-voltage pull-up transistors (e.g., P-type field effect transistors (PFETs)) and low-voltage pull-down transistors (e.g., N-type field effect transistors (NFETs)). For example, each branch can include: a stack of two pull-up transistors and two pull-down transistors, which are series-connected between the second supply voltage node and a ground node; an output node between the two pull-up transistors and the two pull-down transistors in the stack; and an input node connected to a control terminal of a bottom pull-down transistor in the stack. The input node on one branch can be connected to receive an input signal (IN) that switches between V1 and 0.0V, whereas the input node on the other branch can be connected to receive an inverted input signal (INB) that switches between 0.0V and V1. The output node in one branch can output an output signal (OUT) that switches between V2 and 0.0V, whereas the output node in the other branch can output an inverted output signal (OUTB) that switches between 0.0V and V2. Each branch can further an additional pull-up transistor, which is connected between the first positive supply voltage node and an intermediate node between the two pull-up transistors in the stack and which has a control terminal connected to the output node.

These output-connected additional pull-up transistors are included in the structure to prevent voltage swings on the intermediate node that would otherwise result in SOA specification violations. Thus, all transistors within the disclosed structure remain stress-free and exhibit minimal off-state leakage. The disclosed structure is less complex and consumes less chip area than conventional positive voltage level shifters because it does not require any asymmetric high-voltage transistors or the use of external bias voltages to avoid device stress. Finally, an additional advantage of the disclosed structure that the generation of intermediate output signals including an intermediate output signal (OUTM1), which swings between V2 and V1, and an inverted intermediate output signal (OUTM1B), which swings between V1 and V2.

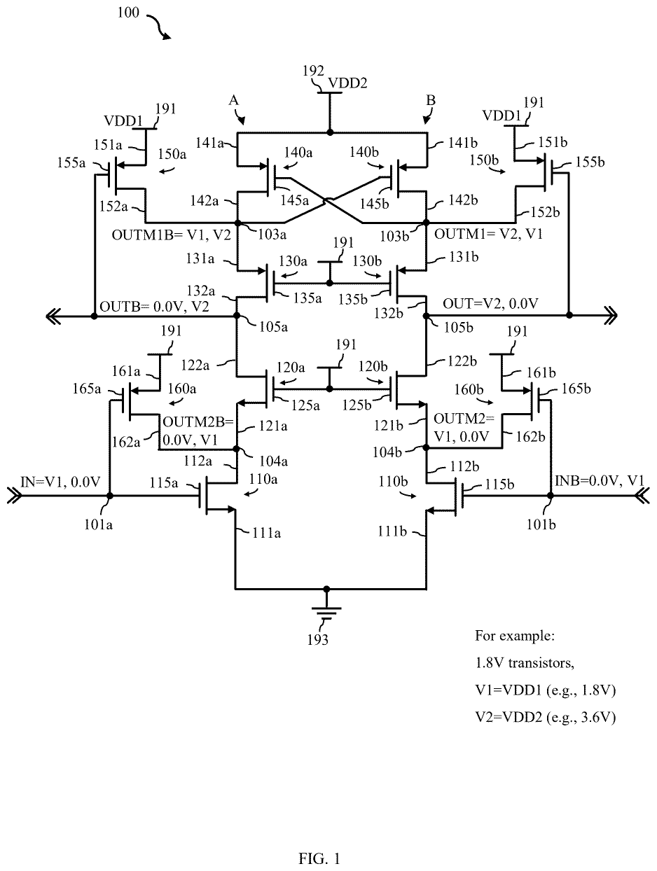

More particularly, FIG. 1 is a schematic diagram illustrating a disclosed embodiment of a positive voltage level shifter 100 (hereinafter referred to as structure 100). Structure 100 can include multiple transistors. As discussed in greater detail below, these transistors can include both pull-up transistors and pull-down transistors. For purposes of this disclosure, a pull-up transistor refers to a transistor configured to pull-up the voltage level on a node when in an on-state, whereas a pull-down transistor refers to a transistor configured to pull-down the voltage level on a node when in an on-state.

For purposes of illustration, the pull-up transistors and pull-down transistors of structure 100 are described below and illustrated in the figures as being metal oxide semiconductor field effect transistors (MOSFETs) and, particularly, P-type field effect transistors (PFETs) and N-type field effect transistors (NFETs), respectively. A MOSFET refers to a transistor that includes at least: a channel region in a semiconductor layer between a source region and a drain region; and a gate adjacent to the channel region. In a PFET, the source/drain regions can include semiconductor material doped so as to have P-type conductivity at a relatively high conductivity level (e.g., so as to be P+ source/drain regions). The channel region can be either doped so as to have N-type conductivity at a relatively low conductivity level (e.g., so as to be an N− channel region) or undoped (e.g., so as to be an intrinsic channel region). In an NFET, the source/drain regions can include semiconductor material doped so as to have N-type conductivity at a relatively high conductivity level (e.g., so as to be N+ source/drain regions). The channel region can be either doped so as to have P-type conductivity at a relatively low conductivity level (e.g., so as to be a P− channel region) or undoped (e.g., so as to be an intrinsic channel region). Examples of dopants that can be employed to achieve P-type or N-type conductivity are discussed in greater detail below. In any case, the gate can include a gate dielectric-gate conductor stack adjacent to the channel region. Various different configurations for PFETs and NFETs are well known in the art and, thus, the details thereof have been omitted from this specification in order to allow the reader to focus on the salient aspects of the disclosed embodiments (e.g., related to the unique voltage level shifter circuit structure).

FIG. 1 and the discussion thereof is, however, not intended to be limiting. For example, in alternative embodiments of structure 100, different types of pull-up and pull-down transistors other than PFETs and NFETs can be employed. For example, the pull-up transistors could be PNP-type bipolar junction transistors (BJTs) or heterojunction bipolar transistors (HBTs) and the pull-down transistors could be NPN-type BJTs or HBTs.

In any case, the transistors within structure 100 can all be low-voltage transistors. Specifically, they can all have the same relatively low maximum voltage rating as specified by the transistor data sheet. For example, the transistors can have a maximum voltage rating of 2.0 volts (V) or lower. In some embodiments, the transistors can be PFETs or NFETs with a maximum voltage rating of 1.8V, of 1.5V or of 0.8V. To minimize manufacturing complexity, the PFETs and NFETs can be symmetric MOSFETs. That is, they can be designed so that the source region and the drain region are the same (e.g., same size, doping, etc.) except for minor process variations and so that the same maximum voltage rating applies to the gate-source voltage (VGS), the gate-drain voltage (VGD), and the drain-source voltage (VDS). As discussed in greater detail below, structure 100 can further be configured to achieve positive voltage level shifting of an input signal (IN), which swings between a relatively low first voltage level (V1) (e.g., of 2.0V or less, such as 1.8V, 1.5V or 0.8V) and 0.0V, to an output signal (OUT), which swings between a relatively high second voltage level (V2) (e.g., V2~2*V1) and 0.0V and to do so without violating of the maximum voltage rating or requiring any external biasing. It should be noted that if IN swings between V1 and 0.0V, ideally OUT would swing between a V2, which is equal to 2*V1, and 0.0V. However, some voltage loss may be exhibited (e.g., up to 10% voltage loss) so that the actual V2 may only be approximately equal to 2*V1 (e.g., up to 10% less than 2*V1).

Specifically, structure 100 can include a first positive supply voltage node 191 (also referred to herein as a first supply voltage node), a second positive supply voltage node 192 (also referred to herein as a second supply voltage node), and a ground node 193. First positive supply voltage node 191 can be electrically connected (e.g., to a first voltage rail) to receive a first positive supply voltage (VDD1). When the first voltage rail is powered on, VDD1 can be at a first voltage level (V1). Second positive supply voltage node 192 can be electrically connected (e.g., to a second voltage rail) to receive a second positive supply voltage (VDD2). When the second voltage rail is powered on, VDD2 can be at a second voltage level (V2), which is higher than V1. V2 can, for example, be essentially double the magnitude of V1. For purposes of this disclosure, “essentially double” the magnitude refers to twice the magnitude, plus or minus approximately 10% thereof (e.g., if V1 is 1.8V, then V2=3.6V+/−0.36V, etc.). Thus, for example, if the maximum voltage rating of the transistors is 1.8V (i.e., if the transistors in structure 100 are 1.8V-transistors), then V1 can be set at 1.8V and V2 can be set at 3.6V. Alternatively, if the maximum voltage rating of the transistors is 1.5V (i.e., if the transistors in structure 100 are 1.5V-transistors), then V1 can be set at 1.5V and V2 can be set at 3.0V. Alternatively, if the maximum voltage rating of the transistors is 0.8V (i.e., if the transistors in structure 100 are 0.8V-transistors), then V1 can be set at 0.8V and V2 can be set at 1.6V. Ground node 193 can be connected to a ground rail (e.g., ground node 193 can be held constant at 0.0V).

As discussed in greater detail below, structure 100 can be connected to receive and output various signals (also referred to herein as voltage pulses). For purposes of this disclosure, a voltage pulse refers to an essentially rectangular direct current voltage signal that transitions (i.e., swings, switches, etc.) between a low voltage level and a high voltage level at regular and repeated intervals such that the voltage pulse is at a low voltage level for a first time period (t1), switches to a higher voltage level and remains at the high voltage level for a second time period (t2) (which is the same as or different from t1), switches back to the low voltage level and again remains at the low voltage level for t1, and so on.

Structure 100 can include a pair of input nodes 101a and 101b. Structure 100 can be connected to receive an input signal (IN) and an inverted input signal (INB) at input nodes 101a and 101b, respectively. IN can transition between V1 and 0.0V. INB can be inverted with respect to IN. That is, INB can be at 0.0V when IN is at V1 and can switch to V1 when IN switches to 0.0V. Structure 100 can further include: a pair of intermediate nodes 103a and 103b (also referred to herein as intermediate output nodes); a pair of additional intermediate nodes 104a and 104b (also referred to herein as additional intermediate output nodes); and a pair of output nodes 105a and 105b (also referred to herein as final output nodes).

Structure 100 can include symmetric branches and, particularly, a first branch A and second branch B. First and second branches A and B can include parallel stacks of transistors connected between second positive supply voltage node 192 and ground node 193. Specifically, first branch A and second branch B can each include: a first pull-up transistor 140a, 140b; a second pull-up transistor 130a, 130b; a first pull-down transistor 120a, 120b; and a second pull-down transistor 110a, 110b, which are electrically connected in series between second positive supply voltage node 192 and ground node 193. Second pull-down transistors 110a, 110b of first and second branches A and B (i.e., the bottom pull-down transistors in the stacks) can have control terminals 115a, 115b, which are electrically connected to input nodes 101a, 101b, respectively, for receiving IN and INB, respectively.

First branch A and second branch B can each include intermediate node 103a, 103b at the junction between first pull-up transistor 140a, 140b and second pull-up transistor 130a, 130b. First branch A and second branch B can each include additional intermediate node 104a, 104b at the junction between first pull-down transistor 120a, 120b and second pull-down transistor 110a, 110b. First branch A and second branch B can each further include output node 105a, 105b at the junction between (i.e., at the interconnect connecting) second pull-up transistor 130a, 130b and first pull-down transistor 120a, 120b.

First pull-up transistors 140a and 140b of first and second branches A and B can be cross coupled. That is, a control terminal 145a of first pull-up transistor 140a in first branch A can be electrically connected to intermediate node 103b of second branch B and a control terminal 145b of first pull-up transistor 140b in second branch B can be electrically connected to intermediate node 103a of first branch A. Additionally, second pull-up transistors 130a and 130b in first and second branches A and B can have control terminals 135a and 135b, respectively, connected to first positive supply voltage node 191. Similarly, first pull-down transistors 120a and 120b in first and second branches A and B can have control terminals 125a and 125b, respectively, connected to first positive supply voltage node 191.

First and second branches A and B can each further include a third pull-up transistor 150a, 150b. Within each branch A and B, third transistor 150a, 150b can be electrically connected between first positive supply voltage node 191 and intermediate node 103a, 103b therein. Furthermore, third pull-up transistor 150a, 150b can have a control terminal 155a, 155b that is electrically connected to output node 105a, 105b, respectively. That is, third pull-up transistors 150a and 150b in first and second branches A and B can be controlled by output signals on output nodes 105a and 105b, respectively, as discussed in greater detail below. First and second branches A and B can each further include a fourth pull-up transistor 160a, 160b. Within each branch A and B, fourth pull-up transistor 160a, 160b can be electrically connected between first positive supply voltage node 191 and additional intermediate node 104a, 104b therein. Furthermore, the fourth pull-up transistor 160a, 160b in a given branch A, B can have a control terminal 165a, 165b connected to the input node 101a, 101b for that given branch A, B.

As mentioned above in some embodiments, the transistors of structure 100 can be MOSFETs. Thus, structure 100 is described in greater detail below as including PFET-type pull-up transistors and NFET-type pull-down transistors. Specifically, first branch A and second branch B can each include: a first PFET 140a, 140b; a second PFET 130a, 130b; a first NFET 120a, 120b; and a second NFET 110a, 110b, which are electrically connected in series between second positive supply voltage node 192 and ground node 193. Specifically, first PFET 140a, 140b can include: a source region 141a, 141b, which is electrically connected to second positive supply voltage node 192; a drain region 142a, 142b, which is electrically connected to an intermediate node 103a, 103b; a channel region between the source region 141a, 141b and the drain region 142a, 142b; and a gate 145a, 145b (i.e., a control terminal) adjacent to the channel region. First PFET 140a and first PFET 140b can be cross coupled. That is, gate 145a of first PFET 140a of first branch A can be electrically connected to intermediate node 103b in second branch B and gate 145b of first PFET 140b of second branch B can be electrically connected to intermediate node 103a in first branch A.

Second PFET 130a, 130b can include: a source region 131a, 131b, which is electrically connected to drain region 142a, 142b at intermediate node 103a, 103b; a drain region 132a, 132b, which is electrically connected to output node 105a, 105b; a channel region between the source region 131a, 131b and the drain region 132a, 132b; and a gate 135a, 135b (i.e., a control terminal) adjacent to the channel region. Gate 135a of second PFET 130a in first branch A and gate 135b of second PFET 130b in second branch B can both be electrically connected to first positive supply voltage node 191.

First NFET 120a, 120b can include: a drain region 122a, 122b, which is electrically connected to drain region 132a, 122b of second PFET 130a, 130b at output node 105a, 105b; a source region 121a, 121b, which is electrically connected to additional intermediate node 104a, 104b; a channel region between the source region 121a, 121b and the drain region 122a, 122b; and a gate 125a, 125b (i.e., a control terminal) adjacent to the channel region. Gate 125a of first NFET 120a in first branch A and gate 125b of first NFET 120b in second branch B can both be electrically connected to first positive supply voltage node 191.

Second NFET 110a, 110b can include: a drain region 112a, 112b, which is electrically connected to source region 121a, 121b of first NFET 120a, 120b at additional intermediate node 104a, 104b; a source region 111a, 111b, which is electrically connected to ground node 193; a channel region between the source region 111a, 111b and the drain region 112a, 112b; and a gate 115a, 115b (i.e., a control terminal) adjacent to the channel region. Gate 115a of second NFET 110a in first branch A and gate 115b of second NFET 110b in second branch B can be electrically connected to input nodes 101a, 101b to receive IN and INB, respectively. That is, second NFET 110a in first branch A and second NFET 110b in second branch B are input-controlled and, more particularly, controlled by input signals IN and INB on input nodes 101a and 101b, respectively.

First and second branches A and B can each also include a third PFET 150a, 150b. Third PFET 150a, 150b can include source region 151a, 151b, which is electrically connected first positive supply voltage node 191; a drain region 152a, 152b, which is electrically connected to intermediate node 103a, 103b; a channel region between the source region 151a, 151b and the drain region 152a, 152b; and a gate 155a, 155b (i.e., a control terminal) adjacent to the channel region. Gate 155a of third PFET 150a in first branch A can be electrically connected to output node 105a, whereas gate 155b of third PFET 150b in second branch B can be electrically connected to output node 105b. That is, third PFETs 150a, 150b are output-controlled.

First and second branches A and B can each further include a fourth PFET 160a, 160b. Fourth PFET 160a, 160b can include source region 161a, 161b, which is electrically connected to first positive supply voltage node 191; a drain region 162a, 162b, which is electrically connected to additional intermediate node 104a, 104b; a channel region between the source region 161a, 161b and the drain region 162a, 162b; and a gate 165a, 165b (i.e., a control terminal) adjacent to the channel region. Gate 165a of fourth PFET 160a in first branch A can be electrically connected to input node 101a, whereas gate 165b of fourth PFET 160b in second branch B can be electrically connected to input node 101b. That is, fourth PFET 160a of first branch A and fourth PFET 160b of second branch B are input-controlled and, more particularly, controlled by IN and INB on input nodes 101a and 101b, respectively.

Configured as described above and in response to IN (which transitions between V1 and 0.0V) at input node 101a and INB (which concurrently transitions between 0.0V and V1) at input node 101b, structure 100 can generate and output various different signals at intermediate nodes 103a, 103b, at additional intermediate nodes 104a, 104b, and at output nodes 105a, 105b. Specifically, in response to IN (which transitions between V1 and 0.0V) at input node 101a and INB (which concurrently transitions between 0.0V and V1) at input node 101b, structure 100 can generate and output an intermediate output signal (OUTM1) (which swings between V2 and V1) at intermediate node 103b within second branch B and an inverted intermediate output signal (OUTM1B) (which concurrently swings between V1 and V2) at intermediate node 103a within first branch A. Additionally, in response to IN (which swings between V1 and 0.0V) at input node 101a and INB (which concurrently swings between 0.0V and V1) at input node 101b, structure 100 can generate and output an additional intermediate output signal (OUTM2) (which swings between V1 and 0.0V) at additional intermediate node 104b within second branch B and an inverted additional intermediate output signal (OUTM2B) (which concurrently swings between 0.0V and V1) at additional intermediate node 104a within first branch A. Finally, in response to IN (which swings between V1 and 0.0V) at input node 101a and INB (which concurrently swings between 0.0V and V1) at input node 101b, structure 100 can generate and output an output signal (OUT) (also referred to herein as a final output signal) (which swings between V2 and 0.0V) at output node 105b within second branch B and an inverted output signal (OUTB) (also referred to herein as an inverted final output signal) (which concurrently swings between 0.0V and V2) at output node 105a within first branch A.

Consider operation of structure 100 of FIG. 1, as described above, where all transistors are 1.8V MOSFETs, V1 is 1.8V, and V2 is 3.6V, particularly when IN is at 1.8V so INB is at 0.0V.

Within first branch A, due to IN being at 1.8V, second NFET 110a is on and fourth PFET 160a is off. As a result, OUTM2B on additional intermediate node 104a is pulled down to 0.0V. When OUTM2B is at 0.0V, first NFET 120a in first branch A is on because its gate 125a is electrically connected to first positive supply voltage node 191 at 1.8V. As a result, OUTB at output node 105a is also pulled down to 0.0V. With OUTB at 0.0V, third PFET 150a is on because its gate 155a is electrically connected to output node 105a and its source region 151a is electrically connected to first positive supply voltage node 191 at 1.8V. As a result, OUTM1B at intermediate node 103a is pulled to 1.8V.

As mentioned above, first PFETs 140a and 140b are cross coupled. Specifically, intermediate node 103a of first branch A is electrically connected to gate 145b of first PFET 140b in second branch B, whereas intermediate node 103b of second branch B is electrically connected to gate 145a of first PFET 140a in first branch A. Since OUTM1B on intermediate node 103a is at 1.8V and source region 141b of that first PFET 140b is electrically connected to second positive supply voltage node 192 at 3.6V, first PFET 140b in second branch B is on and pulls up OUTM1 on intermediate node 103b to 3.6V. Since OUTM1 on gate 145a of first PFET 140a is at 3.6V and source region 141a of that first PFET 140a is electrically connected to second positive supply voltage node 192 at 3.6V, first PFET 140a is off such that OUTM1B on intermediate node 103a stays at 1.8V. It should be noted that second PFET 130a will also be off because its gate 135a is electrically connected to first positive supply voltage node 191 at 1.8V and its source region 131 a is connected to intermediate node 103a, which is also at 1.8V.

Within second branch B, source region 131b of second PFET 130b is electrically connected to intermediate node 103b. Since OUTM1 thereon is at 3.6V and gate 135b of second PFET 130b is electrically connected to first positive supply voltage node 191 at 1.8V, second PFET 130b is on and OUT at output node 105b is pulled up to 3.6V. Furthermore, since INB (which is at 0.0V) is applied to gate 115b of second NFET 110b and to gate 165b of fourth PFET 160b, second NFET 110b is off and fourth PFET 160b is on. Thus, OUTM2 on additional intermediate node 104b is pulled up to 1.8V. Since source region 121b of first NFET 120b (which is electrically connected to additional intermediate node 104b) is at 1.8V and gate 125b of first NFET 120b (which is electrically connected to first positive supply voltage node 191) is also at 1.8V, first NFET 120b is off. Thus, OUT at output node 105b is maintained at 3.6V.

Consider operation of this same structure (i.e., where all transistors are MOSFETs, V1 is 1.8V, and V2 is 3.6V) when IN is 0.0V and INB is 1.8V.

Within second branch B, due to INB being at 1.8V, second NFET 110b is on and fourth PFET 160b is off. As a result, OUTM2 on additional intermediate node 104b is pulled down to 0.0V. When OUTM2 is at 0.0V, first NFET 120b in second branch B is on because its gate 125b is electrically connected to first positive supply voltage node 191 at 1.8V. As a result, OUT at output node 105b is also pulled down to 0.0V. With OUT at 0.0V, third PFET 150b is on because its gate 155b is electrically connected to output node 105b and its source region 151b is electrically connected to first positive supply voltage node 191 at 1.8V. As a result, OUTM1 at intermediate node 103b is pulled to 1.8V.

As mentioned above, first PFETs 140a and 140b are cross coupled. Specifically, intermediate node 103a of first branch A is electrically connected to gate 145b of first PFET 140b in second branch B, whereas intermediate node 103b of second branch B is electrically connected to gate 145a of first PFET 140a in first branch A. Since OUTM1 on intermediate node 103b is at 1.8V and source region 141a of that first PFET 140a is electrically connected to second positive supply voltage node 192 at 3.6V, first PFET 140a in first branch A is on and pulls up OUTM1B on intermediate node 103a to 3.6V. Since OUTM1B on gate 145b of first PFET 140b is at 3.6V and source region 141b of that first PFET 140b is electrically connected to second positive supply voltage node 192 at 3.6V, first PFET 140b is off such that OUTM1 on intermediate node 103b stays at 1.8V. It should be noted that second PFET 130b will also be off because its gate 135b is electrically connected to first positive supply voltage node 191 at 1.8V and its source region 131b is connected to intermediate node 103b, which is also at 1.8V.

Within first branch A, source region 131a of second PFET 130a is electrically connected to intermediate node 103a. Since OUTM1B thereon is at 3.6V and gate 135a of second PFET 130a is electrically connected to first positive supply voltage node 191 at 1.8V, second PFET 130a is on and OUTB at output node 105a is pulled up to 3.6V. Furthermore, since IN (which is at 0.0V) is applied to gate 115a of second NFET 110a and to gate 165a of fourth PFET 160a, second NFET 110a is off and fourth PFET 160a is on. Thus, OUTM2B on additional intermediate node 104a is pulled up to 1.8V. Since source region 121a of first NFET 120a (which is electrically connected to additional intermediate node 104a) is at 1.8V and gate 125a of first NFET 120a (which is electrically connected to first positive supply voltage node 191) is also at 1.8V, first NFET 120a is off. Thus, OUTB on output node 105a is maintained at 3.6V.

As illustrated, during operation of structure 100, the maximum voltage differential between any two terminals (e.g., S-D, G-S, G-D) of any transistor is at or below the transistor voltage rating (e.g., of 1.8V). Thus, all transistors are stress free.

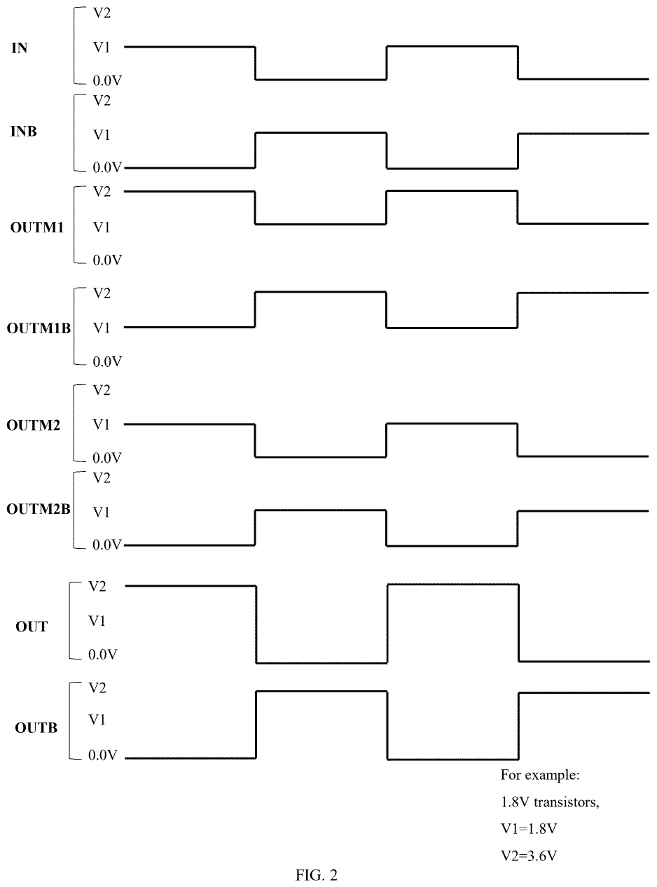

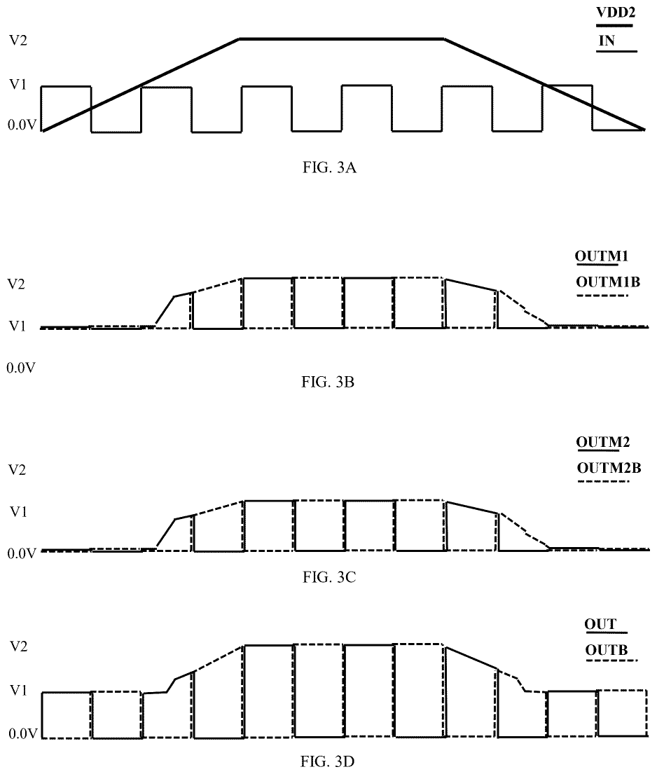

FIGS. 3A-3D are timing diagrams illustrating some of the voltage pulses of FIG. 2 during power-up and power down of the structure of FIG. 1 and, particularly, of the second positive supply voltage node 192 therein. Specifically, FIG. 3A illustrates IN (which switches between 0.0V and V1 (e.g., 1.8V) during power-up and power-down of second positive supply voltage node 192 from 0.0V to V2 (e.g., 3.6V). FIG. 3B illustrates concurrent toggling of OUTM1 and OUTM1B during power-up and power-down of second positive supply voltage node 192. FIG. 3C illustrates concurrent toggling of OUTM2 and OUTM2B during power-up and power-down of second positive supply voltage node 192. Finally, FIG. 3D illustrates concurrent toggling of OUT and OUTB during power-up and power-down of second positive supply voltage node 192. As illustrated in FIGS. 3B-3C, increases and decreases in the amplitudes of the illustrated voltage pulses (e.g., OUTM1, OUTM1B, OUTM2, OUTMB, OUT, and OUTB) during power-up and power-down, respectively, track the increases and decreases in the voltage level on the second positive supply voltage node 192. Thus, there is no output signal interchange or mismatch during power-up or power-down and the structure 100 is operable without requiring, for example, any node pre-charge operations at power-up.

It should be understood that in the structures and methods described above, a semiconductor material refers to a material whose conducting properties can be altered by doping with an impurity. Exemplary semiconductor materials include, for example, silicon-based semiconductor materials (e.g., silicon, silicon germanium, silicon germanium carbide, silicon carbide, etc.) and III-V compound semiconductors (i.e., compounds obtained by combining group III elements, such as aluminum (Al), gallium (Ga), or indium (In), with group V elements, such as nitrogen (N), phosphorous (P), arsenic (As) or antimony (Sb)) (e.g., GaN, InP, GaAs, or GaP). A pure semiconductor material and, more particularly, a semiconductor material that is not doped with an impurity for the purposes of increasing conductivity (i.e., an undoped semiconductor material) is referred to in the art as an intrinsic semiconductor. A semiconductor material that is doped with an impurity for the purposes of increasing conductivity (i.e., a doped semiconductor material) is referred to in the art as an extrinsic semiconductor and will be more conductive than an intrinsic semiconductor made of the same base material. That is, extrinsic silicon will be more conductive than intrinsic silicon; extrinsic silicon germanium will be more conductive than intrinsic silicon germanium; and so on. Furthermore, it should be understood that different impurities (i.e., different dopants) can be used to achieve different conductivity types (e.g., P-type conductivity and N-type conductivity) and that the dopants may vary depending upon the different semiconductor materials used. For example, a silicon-based semiconductor material (e.g., silicon, silicon germanium, etc.) is typically doped with a Group III dopant, such as boron (B) or indium (In), to achieve P-type conductivity, whereas a silicon-based semiconductor material is typically doped with a Group V dopant, such as arsenic (As), phosphorous (P) or antimony (Sb), to achieve N-type conductivity. A gallium nitride (GaN)-based semiconductor material is typically doped with magnesium (Mg) to achieve P-type conductivity and with silicon (Si) or oxygen to achieve N-type conductivity. Those skilled in the art will also recognize that different conductivity levels will depend upon the relative concentration levels of the dopant(s) in a given semiconductor region.

It should be understood that the terminology used herein is for the purpose of describing the disclosed structures and methods and is not intended to be limiting. For example, as used herein, the singular forms “a,” “an” and “the” are intended to include the plural forms as well, unless the context clearly indicates otherwise. Additionally, as used herein, the terms “comprises,” “comprising,” “includes” and/or “including” specify the presence of stated features, integers, steps, operations, elements, and/or components, but do not preclude the presence or addition of one or more other features, integers, steps, operations, elements, components, and/or groups thereof. Furthermore, as used herein, terms such as “right,” “left,” “vertical,” “horizontal,” “top,” “bottom,” “upper,” “lower,” “under,” “below,” “underlying,” “over,” “overlying,” “parallel,” “perpendicular,” etc., are intended to describe relative locations as they are oriented and illustrated in the drawings (unless otherwise indicated) and terms such as “touching,” “in direct contact,” “abutting,” “directly adjacent to,” “immediately adjacent to,” etc., are intended to indicate that at least one element physically contacts another element (without other elements separating the described elements). The term “laterally” is used herein to describe the relative locations of elements and, more particularly, to indicate that an element is positioned to the side of another element as opposed to above or below the other element, as those elements are oriented and illustrated in the drawings. For example, an element that is positioned laterally adjacent to another element will be beside the other element, an element that is positioned laterally immediately adjacent to another element will be directly beside the other element, and an element that laterally surrounds another element will be adjacent to and border the outer sidewalls of the other element. The corresponding structures, materials, acts, and equivalents of all means or step plus function elements in the claims below are intended to include any structure, material, or act for performing the function in combination with other claimed elements as specifically claimed.

The descriptions of the various disclosed embodiments have been presented for purposes of illustration but are not intended to be exhaustive or limiting. Many modifications and variations will be apparent to those of ordinary skill in the art without departing from the scope and spirit of the disclosed embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A voltage level shifter comprising:
a first supply voltage node;
a second supply voltage node; and
two branches, wherein each branch includes:
a first pull-up transistor connected between the second supply voltage node and an intermediate node;
a second pull-up transistor connected between the intermediate node and an output node; and
a third pull-up transistor connected between the first supply voltage node and the intermediate node, wherein the third pull-up transistor includes a control terminal connected to the output node.

2. The voltage level shifter of claim 1,
wherein the two branches include a first branch and a second branch, and
wherein the first pull-up transistor in the first branch and the first pull-up transistor in the second branch are cross coupled.

3. The voltage level shifter of claim 1,
wherein the two branches include a first branch and a second branch, and
wherein the second pull-up transistor in the first branch and the second pull-up transistor in the second branch have control terminals connected to the first supply voltage node.

4. The voltage level shifter of claim 1, further comprising: a ground node, wherein each branch further includes:
a first pull-down transistor connected between the output node and an additional intermediate node;
a second pull-down transistor connected between the additional intermediate node and the ground node; and
a fourth pull-up transistor connected between the first supply voltage node and the additional intermediate node, wherein the second pull-down transistor and the fourth pull-up transistor include control terminals connected to an input node.

5. The voltage level shifter of claim 4, wherein the first pull-up transistor, the second pull-up transistor, the third pull-up transistor, the fourth pull-up transistor, the first pull-down transistor, and the second pull-down transistor are symmetric transistors with a same voltage-rating.

6. The voltage level shifter of claim 4,
wherein the two branches include a first branch and a second branch, and
wherein the first pull-down transistor in the first branch and the first pull-down transistor in the second branch have control terminals connected to the first supply voltage node.

7. The voltage level shifter of claim 4,
wherein the two branches include a first branch and a second branch,
wherein the input node in the first branch is connected to receive an input signal that swings between a first voltage level and ground, and
wherein the input node in the second branch is connected to receive an inverted input signal.

8. The voltage level shifter of claim 7,
wherein the first supply voltage node is connected to receive a first supply voltage at the first voltage level,
wherein the second supply voltage node is connected to receive a second supply voltage at a second voltage level that is greater than the first voltage level, and
wherein the ground node is at 0.0 volts.

9. The voltage level shifter of claim 8, wherein the second voltage level is approximately twice the first voltage level.

10. The voltage level shifter of claim 8,
wherein the intermediate node in the second branch outputs an intermediate signal that swings between the second voltage level and the first voltage level and the intermediate node in the first branch outputs an inverted intermediate signal, and
wherein the output node in the second branch outputs an output signal that swings between the second voltage level and 0.0V and the output node in the first branch outputs an inverted output signal.

11. A voltage level shifter comprising:
a first supply voltage node;
a second supply voltage node; and
two branches, wherein each branch includes:
a first P-type field effect transistor (PFET) connected between the second supply voltage node and an intermediate node;
a second PFET connected between the intermediate node and an output node; and
a third PFET connected between the first supply voltage node and the intermediate node, wherein the third PFET includes a gate connected to the output node.

12. The voltage level shifter of claim 11,
wherein the two branches include a first branch and a second branch,
wherein the first PFET in the first branch and the first PFET in the second branch are cross-coupled, and
wherein the second PFET in the first branch and the second PFET in the second branch have gates connected to the first supply voltage node.

13. The voltage level shifter of claim 11, further comprising: a ground node, wherein each branch further includes:
a first N-type field effect transistor (NFET) connected between the output node and an additional intermediate node;
a second NFET connected between the additional intermediate node and the ground node; and
a fourth PFET connected between the first supply voltage node and the additional intermediate node, wherein the second NFET and the fourth PFET include gates connected to an input node.

14. The voltage level shifter of claim 13, wherein the first PFET, the second PFET, the third PFET, the fourth PFET, the first NFET, and the second NFET are symmetric transistors with a same voltage-rating.

15. The voltage level shifter of claim 13,
wherein the two branches include a first branch and a second branch, and
wherein the first NFET in the first branch and the second NFET in the second branch have gates connected to the first supply voltage node.

16. The voltage level shifter of claim 13,
wherein the two branches include a first branch and a second branch,
wherein the input node in the first branch is connected to receive an input signal that swings between a first voltage level and ground, and
wherein the input node in the second branch is connected to receive an inverted input signal.

17. The voltage level shifter of claim 16,
wherein the first supply voltage node is connected to receive a first supply voltage at the first voltage level,
wherein the second supply voltage node is connected to receive a second supply voltage at a second voltage level that is greater than the first voltage level, and
wherein the ground node is at 0.0 volts.

18. The voltage level shifter of claim 17, wherein the second voltage level is approximately twice the first voltage level.

19. The voltage level shifter of claim 17,
wherein the intermediate node of the second branch outputs an intermediate signal that swings between the second voltage level and the first voltage level and the intermediate node in the first branch outputs an inverted intermediate signal, and
wherein the output node in the second branch outputs an output signal that swings between the second voltage level and 0.0V and the output node in the first branch outputs an inverted output signal.

20. A voltage level shifter comprising:
a first supply voltage node;
a second supply voltage node;
a ground node; and
two branches including a first branch and a second branch,
wherein the first branch and the second branch each include:
a first pull-up transistor, a second pull-up transistor, a first pull-down transistor, and a second pull-down transistor connected in series between the second supply voltage node and the ground node;
a third pull-up transistor connected between the first supply voltage node and an intermediate node between the first pull-up transistor and the second pull-up transistor, wherein the third pull-up transistor includes a control terminal connected to an output node between the second pull-up transistor and the first pull-down transistor; and
a fourth pull-up transistor connected between the first supply voltage node and an additional intermediate node between the first pull-down transistor and the second pull-down transistor, wherein the second pull-down transistor and the fourth pull-up transistor include control terminals connected to an input node,
wherein the first pull-up transistor in the first branch and the first pull-up transistor in the second branch are cross coupled, and
wherein the second pull-up transistor in the first branch, the second pull-up transistor in the second branch, the first pull-down transistor in the first branch, and the first pull-down transistor in the second branch have control terminals connected to the first supply voltage node.
